(19) United States
(12) Patent Application Publication
(10) Pub. No.: US 2008/0245555 A1
(43) Pub. Date: Oct. 9, 2008

(54) CIRCUIT SUBSTRATE WITH PLATED THROUGH HOLE STRUCTURE AND METHOD

(75) Inventors: Yue Li, Markham (CA); Vincent Chan, Richmond Hill (CA); Neil Mclellan, Toronto (CA); Liane Martinez, North York (CA)

Correspondence Address: ADVANCED MICRO DEVICES, INC.;C/O VEDDER PRICE P.C., 222 N.LASALLE STREET, CHICAGO, IL, 60601, US

(73) Assignee: ATI Technologies ULC, Markham (CA)

(21) Appl. No.: 11/696,285

(22) Filed: Apr. 4, 2007

(51) Int. Cl. H05K 1/11; H01R 12/04

(52) U.S. Cl. 174/262

(57) ABSTRACT

A circuit substrate includes an outer plated through hole structure and an inner plated through hole structure located within the outer plated through hole structure. In one example, the circuit substrate includes a core and an outer plated through hole structure having a first metal layer configured over the core to form an outer plated through hole. The circuit substrate also includes an inner plated through hole structure located within the outer plated through hole structure having a second metal layer positioned inside of the outer plated through hole with an insulation layer interposed between the first and second metal layers. Methods for making such a circuit substrate are also described.

### FIELD OF THE DISCLOSURE

The disclosure generally relates to circuit substrates, and more particularly to a circuit substrates having plated through hole structures therein.

### BACKGROUND OF THE DISCLOSURE

Devices, such as electronic devices, often require electrical connections to perform the desired functions. These electrical connections may be required to carry power or signals to analog and/or digital electronic components. As known in the art, circuit substrates, such as multi-layer printed circuit boards and other structures mechanically support electronic/optical components, such as circuit assemblies, surface-mount devices, memory, transistors, resistors, integrated circuits (“ICs”), flip chips, or any other suitable electronic/optical component or mechanical component as known in the art. As also known in the art, substrates also electrically connect the electronic components using conductive pathways (e.g., traces), which are often etched from copper that is over a non-conductive material.

A circuit assembly may include a circuit substrate and one or more electronic circuits or components. Circuit assemblies may then be used in a device to perform a desired function. Devices that may use circuit assemblies having circuit substrates include, for example, wireless phones, mobile and/or stationary computers, printers, LAN interfaces (wireless and/or wired), media players, video encoders and/or decoders, and/or any other suitable devices.

As known in the art, circuit substrates may have multiple conductive layers and contain at least one insulation layer (the non-conductive material), although circuit substrates may contain any number of layers as known in the art. Conductive layers are used to provide the desired electrical connections and perform other desired functionality. It is often necessary to electrically connect the conductive layers to pass signals, power, or ground from one layer to one or more other layers or from one layer to an electric circuit or component. As known in the art, holes may be formed in the circuit substrates to make these desired electrical connections. These holes, often referred to as through holes, pass-through holes, or plated through holes, are often plated with a conductive material, such as copper, gold, or any other suitable material, to form plated through hole structures to connect one conductive trace or layer to one or more other conductive traces or layers in the circuit substrate.

FIGS. 1 through 6 illustrate such a circuit substrate in different stages of manufacture, as is known in the art. As shown in FIG. 1, a core or insulation core 100 is interposed between a first metal layer portion 102 and a second metal layer portion 104. FIG. 2 shows two through hole structures 106, 108 defined at least in part by inner surfaces 110, 112 of the core 100. These through hole structures 106, 108 may be formed by mechanical drilling, laser drilling, or any other suitable method as known by one skilled in the art. FIG. 2 also shows etched areas collectively labeled 114. These etched areas 114 have been etched as known in the art and may or may not be continuous areas, i.e., they may be separated by the traces, which are the portions remaining after the etching of the first metal layer portion 102 and second metal layer portion 104. FIG. 3 shows the addition of a conductive material 116, 118 to plate the through hole structures 106, 108. This conductive material may be copper, gold, or any other suitable conductive material as known in the art. The conductive material 116, 118 electrically connects the different layers of the circuit substrate. This plating thus forms two axially separate plated through hole structures 120, 122 in this example. For example, plated through hole structure 120 includes a portion of first metal layer portion 102, conductive material 116, and a portion of second metal layer portion 104. Similarly, plated through hole 122 includes a portion of first metal layer portion 102, conductive material 118, and a portion of the second metal layer portion 104.

Often, additional layers are added to a circuit substrate beyond the layers shown in FIG. 3. In FIG. 4, for example, an insulation layer 124, 126, often an epoxy, is placed within plated through holes 120, 122. Insulation layers 128 and 130 may also be formed; insulation layer 128 is on metal layer portion 102 and insulation layer 130 is on metal layer portion 104. It should be understood that insulation core 100, insulation layers 128, 130, and insulation layers 124, 126 may be composed of the same material or may be different. If desired, additional metal layer portions 132, 134 may be added to the circuit substrate.

As shown in FIG. 5, etching creates additional traces, and drilling creates additional electrically conductive portions, e.g., micro vias or vias. For example, metal layer portion 132 has been etched at locations designated 136, 138, 140, 142, 144, and metal layer portion 134 has been etched at locations designated 146, 148, 150, 152, and 154. Furthermore, holes for electrically conductive portions, e.g., micro vias, have been drilled as shown at locations 156, 158, 160, 162, 164, 166, and 168. FIG. 6 then shows the result after the micro vias 156, 158, 160, 162, 164, 166, and 168 are plated. For example, an electrical connection is made between metal layer portions 102 and 132 at locations 156, 158, 160, and 162. An electrical connection is made between metal layer portions 104 and 134 at locations 164, 166, and 168. As understood by one skilled in the art, however, it should be noted that although, for example, metal layer portion 102 is being electrically connected to metal layer portion 104 (as shown in FIG. 3 with the conductive material 116, 118) and similarly to other metal layer portions 132 and 134 (as shown in FIG. 6), the etching process, applied during different builds, allows a single metal layer portion to form different traces and thus carry different electrical signal. Furthermore, as understood by one having ordinary skill in the art, this process of adding build layers, i.e., adding metal layer portions and insulation layers, etching, drilling through holes, and plating through holes to form electrical connections between different layers may be repeated as desired to form additional layers and electrical connections between the layers for a circuit substrate.

One issue with plated through hole structures, however, is inductance and capacitance among different plated through holes when they conduct electrical signals. This problem becomes more prevalent with higher frequency signals. As a result, noise occurs during power delivery, and signal quality can be affected.

One method used to try to overcome this problem is to reduce the height or thickness of the insulation core. As shown in FIG. 1, for example, thickness 170 may be decreased. Another solution has been to add more plated through holes such that a plated through hole for ground is closer to each plated through hole that carries a signal or delivers power. For example, distance 172 shown in FIG. 3 between the center of plated through hole 120 and the center of plated through hole 122 may be decreased. These solutions, however, are not without their own problems. Both of these solutions, for example, affect a circuit substrate's mechanical robustness, which therefore reduces a product's reliability. For example, decreasing the thickness of an insulation core or forming more through holes may cause a circuit substrate to become flimsy. In addition, the allowed distance between centers is limited by circuit layout constraints.

It is therefore desirable to provide, among other things, a plated through hole structure that can reduce inductance without the disadvantages and problems associated with known techniques.

### BRIEF DESCRIPTION OF THE DRAWINGS

A circuit substrate with plated through hole structure and method will be more readily understood in view of the following description when accompanied by the figures below and wherein like reference numerals represent like elements:

FIG. 1 is an example of a prior art circuit substrate during one stage of manufacture;

FIG. 2 is an example of a prior art circuit substrate during one stage of manufacture;

FIG. 3 is an example of a prior art circuit substrate during one stage of manufacture;

FIG. 4 is an example of a prior art circuit substrate during one stage of manufacture;

FIG. 5 is an example of a prior art circuit substrate during one stage of manufacture;

FIG. 6 is an example of a prior art circuit substrate during one stage of manufacture;

FIG. 7 is an example of circuit substrate, having a plated through hole structure within another plated through hole structure, operatively coupled to an electronic component;

FIG. 8 is an exemplary cross-sectional view of a circuit substrate having a plated through hole structure within another plated through hole structure shown in FIG. 7;

FIG. 9 is a partial cross sectional view of a circuit substrate having a plated through hole structure within another plated through hole structure;

FIG. 10 is a flowchart that depicts one example of a method for making a circuit substrate having a plated through hole structure within another plated through hole structure;

FIG. 11 is another flowchart that depicts one example of a method for making a circuit substrate having a plated through hole structure within another plated through hole structure;

FIG. 12 is an example of a circuit substrate during one stage of manufacture;

FIG. 13 is an example of a circuit substrate during one stage of manufacture;

FIG. 14 is an example of a circuit substrate during one stage of manufacture;

FIG. 15 is an example of a circuit substrate during one stage of manufacture;

FIG. 16 is an example of a circuit substrate during one stage of manufacture;

FIG. 17 is an example of a circuit substrate during one stage of manufacture;

FIG. 18 is an example of a circuit substrate during one stage of manufacture;

FIG. 19 is an example of a circuit substrate during one stage of manufacture;

FIG. 19 is an example of a circuit substrate during one stage of manufacture;

FIG. 20 is an example of a circuit substrate during one stage of manufacture;

FIG. 21 is an example of a circuit substrate during one stage of manufacture;

FIG. 22 is a block diagram showing a circuit assembly having a circuit substrate with a plated through hole structure within another plated through hole structure; and

FIG. 23 is a block diagram of a device having a circuit substrate with a plated through hole structure within another plated through hole structure.

### DETAILED DESCRIPTION OF THE DISCLOSURE

Briefly, a circuit substrate may have at least an outer plated through hole structure and at least an inner plated through hole structure located within the outer plated through hole structure. The circuit substrate may further include an insulation material interposed between the outer plated through hole structure and the inner plated through hole structure, and furthermore, the inner plated through hole structure may be concentrically located within the outer plated through hole structure. Among other things, having an inner plated through hole structure located within an outer plated through hole structure in a circuit substrate allows ground, power, and/or signals to pass between different layers of the circuit substrate while minimizing negative effects caused by inductance. Furthermore, the mechanical robustness of the circuit substrate is not unduly diminished. Other advantages will be recognized by one of ordinary skill in the art.

In one example, the circuit substrate may include a core, and the outer plated through hole structure includes a first metal layer configured over the core defining an outer plated through hole structure. Furthermore, the circuit substrate may include an inner plated through hole structure located within the outer plated through hole structure that includes a second metal layer positioned inside of the outer plated through hole with an insulation material interposed between the first metal layer of the outer plated through hole structure and the second layer of the inner plated through hole structure.

In one example, a circuit substrate may include an inner plated through hole structure that has electrically conductive portions that electrically couple metal of an inner plated through hole structure to other layers of the substrate. In one example, a circuit assembly may include a circuit substrate as described throughout with at least one electronic circuit operatively coupled to the substrate. In one example, a device may include a circuit assembly as discussed throughout.

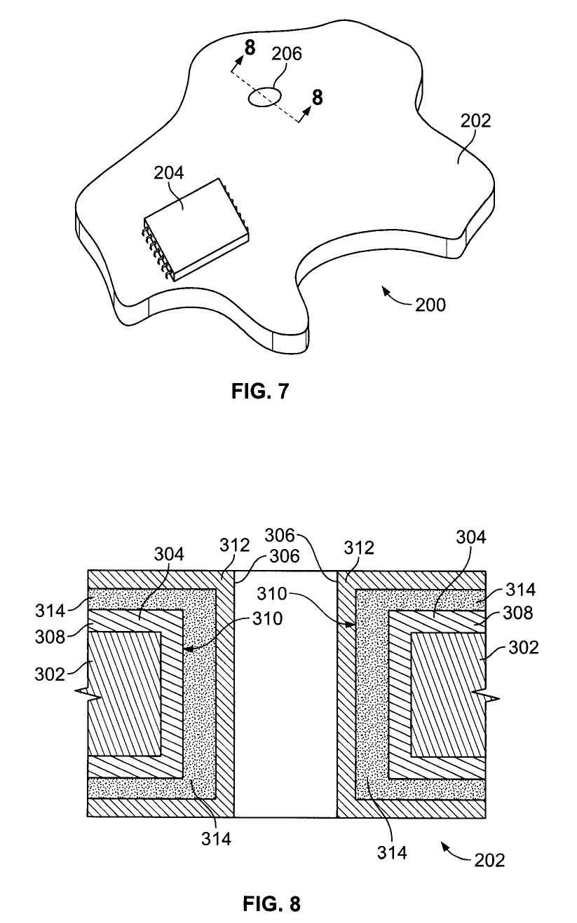

Referring now to FIG. 7, one example of a circuit assembly 200 is shown. Circuit assembly 200 includes a circuit substrate 202 and an electronic circuit 204 operatively coupled to the circuit substrate 202. Electronic component 204 may be an integrated circuit, (packaged or unpackaged) such as CPU core or GPU core, memory, resistor, a capacitor or any other suitable electronic component(s). Circuit substrate 202 also includes a novel plated through hole structure 206 that contains at least an outer plated through hole structure and at least an inner plated through hole structure located within the outer plated through hole structure so that they are axially aligned.

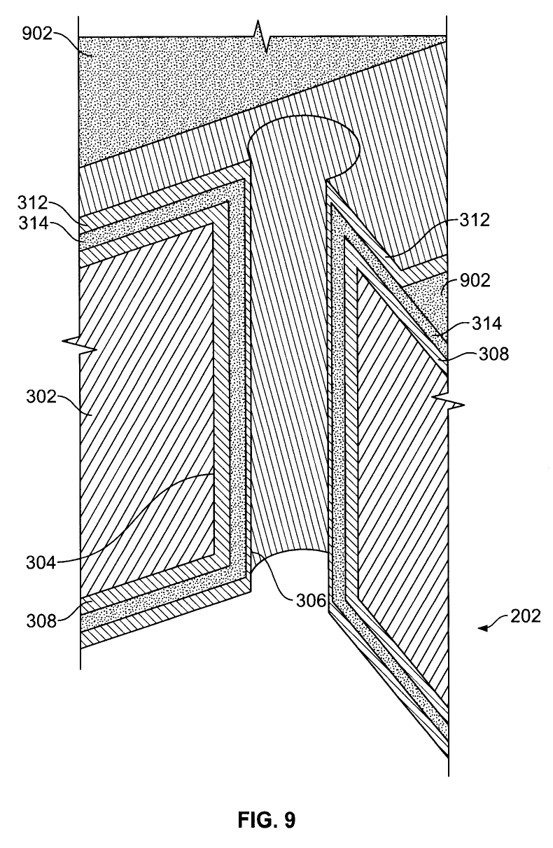

FIG. 8 shows a cross sectional view of the circuit substrate 202 taken along line 8-8 in FIG. 7. Circuit substrate 202 contains a core insulator 302, which may be made from an insulation material as known in the art. Circuit substrate 202 also contains outer plated through hole structure 304 and inner plated through hole structure 306 located within the outer plated through hole structure 304. Outer plated through hole structure 304 contains first metal layer 308 configured over the core 302 to define an outer plated through hole 310. Inner plated through hole structure 306 contains a second metal layer 312 positioned inside of the outer plated through hole 310. An insulation material 314, such an epoxy or other suitable material as known in the art, is interposed between the first metal layer 308 of the outer plated through hole structure 304 and the second metal layer 312 of the inner plated through hole structure 306. The inner plated through hole structure 306 may be concentrically located within the outer plated through hole structure 304 or it may be offset if desired. Furthermore, the outer plated through hole structure 304 may include a portion configured in a cylindrical shape, and the inner plated through hole structure 306 may include a portion configured in a cylindrical shape. However, any suitable shapes may be used.

FIG. 9 shows another view of circuit substrate 202 with the plated through hole structure 206. A top surface generally designated 902 may include electrical traces, ground plane, other plated through holes etc. By way of illustration, the outer plated through hole may be connected to a ground potential whereas the inner plated through hole may be coupled to a high frequency signal trace coming from a high speed bus or other high speed signal source. The distance between the ground potential and the signal trace is minimal, namely the thickness of the insulation material 314. Reducing the distance between the different plated through holes having different voltage potentials can reduce the inductance. It will also be recognized that a power potential or voltage supply potential may be coupled to one of the plated through holes whereas ground or signals may be coupled to the other plated through hole. It will be recognized that any signals or ground potential or voltages or any other signals may be connected to the plated through holes, depending upon the desired application.

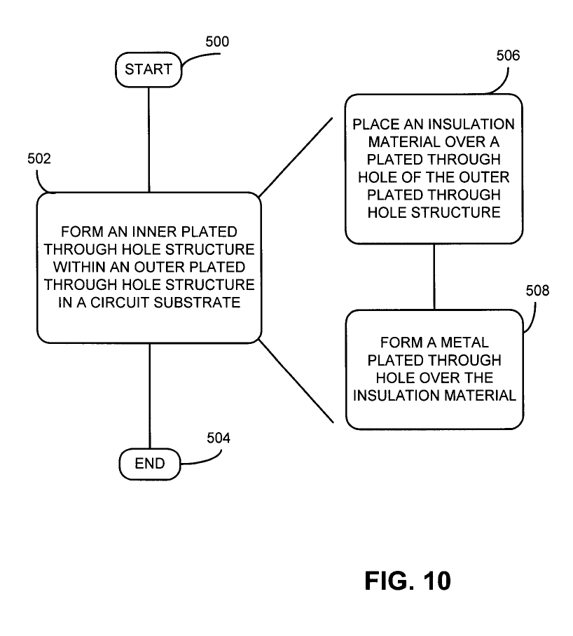

FIG. 10 briefly shows one example of a method for making a circuit substrate, starting with block 500. The method includes forming an inner plated through hole structure within an outer plated through hole structure in a circuit substrate, as shown in block 502. Although the method may end as shown in block 504, the method may include other steps. For example, the method may further include forming the plated through holes by placing an insulation material over a plated through hole of the outer plated through hole structure as shown in block 506. The insulation material may be an epoxy, as known in the art, or any other suitable material. The method may also include forming a metal plated through hole over the insulation material, as shown in block 508. As one of ordinary skill in the art would understand, this process may include additional steps and the steps may be performed in any suitable order. For example, after placing insulation material over a plated through hole of the outer plated through hole structure, one may need to drill out some of the insulation material to form an inner plated through hole over the insulation material. As also recognized, the holes are defined by surfaces of material.

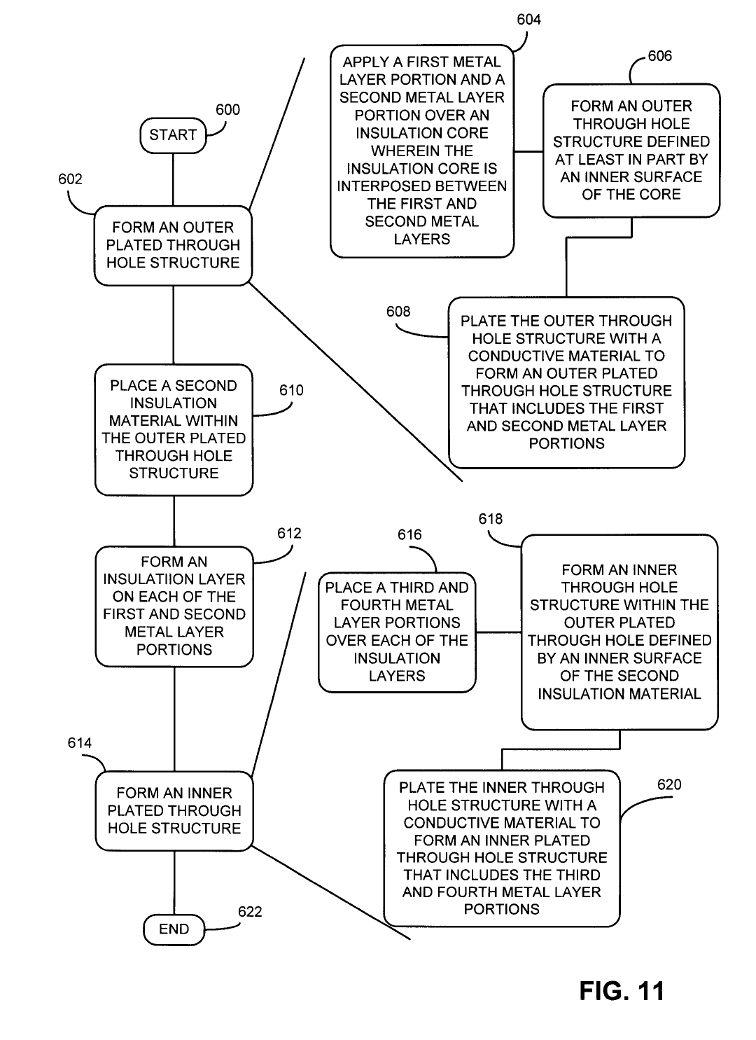

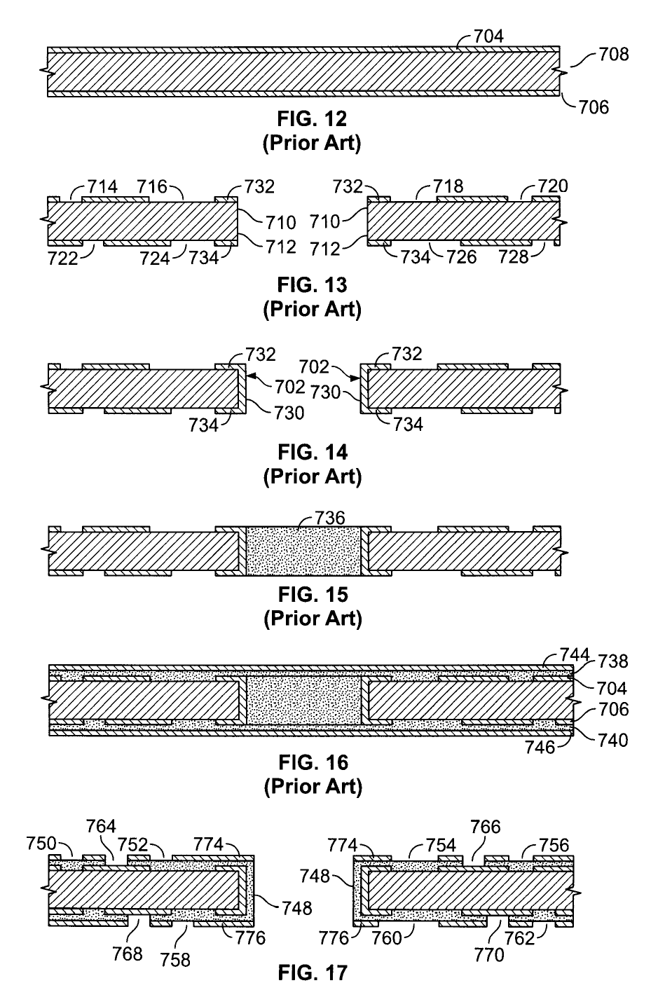

FIG. 11 is another block diagram illustrating another example of a method for making a circuit substrate having an inner plated through hole structure located within an outer plated through hole structure. In FIGS. 12 through 21, a circuit substrate is shown in various stages of manufacture to help better illustrate the example. Thus, FIGS. 11 through 21 will be discussed together.

A method for making a circuit substrate begins in block 600. As shown in block 602, the method includes forming an outer plated through hole structure 702. An outer plated through hole structure 702 may be formed by applying a first metal layer portion 704 and a second metal layer portion 706 over an insulation core 708 such that the insulation core 708 is interposed between the first and second metal layer portions 704, 706, as shown in block 604. As discussed throughout, the metal layer portions may be any suitable material, such as copper gold, alloys or any suitable material. The method then involves forming an outer through hole structure 710 defined at least in part by an inner surface 712 of the insulation core 708, shown in block 606. The outer through hole structure 710, shown in FIG. 13, may be formed by any suitable method recognized by one having ordinary skill in the art, which may include, for example, drilling or using a laser. As also shown in FIG. 13 and as known by one having ordinary skill in the art, the first metal layer portion 704 and second metal layer portion 706 may also be etched such that the remaining material of metal layer portions 704 and 706 form traces to carry power, ground or signals to/from a circuit or component. This etching may leave conductive traces or areas between etched regions such as 714, 716, 718, 720, 722, 724, 726, and 728. Finally, as shown in block 608, the method involves plating the outer through hole structure 710 with a conductive material 730, such as copper or gold or any other suitable material, to form an outer plated through hole structure 702. As shown in FIG. 14, the outer plated through hole structure 702 includes the conductive material 730, and portions of the first and second metal layer portions, generally designated 732 and 734.

The method continues with block 610 and involves placing a second insulation material 736 within the outer plated through hole structure 702. As previously discussed, second insulation material 736 shown in FIG. 15, may be of the same type as any other insulation material, such as the insulation core or other insulation layers. Insulation layers are often, for example, made from a suitable epoxy. Next, as shown in block 612, the method involves placing an insulation layer 738, 740 (illustrated in FIG. 16) on each of the first and second metal layer portions 704, 706.

The next step, shown in block 614, includes forming an inner plated through hole structure. This step includes the steps shown in blocks 616, 618, and 620, which are similar to the steps 604, 606, and 608. First, as shown in block 616, forming an inner plated through hole structure 742 includes placing a third metal layer portion 744 and a fourth metal layer portion 746 on each of the insulation layers 738, 740. As shown in FIG. 16, for example, third metal layer portion 744 is placed on insulation layer 738, and fourth metal layer portion 746 is placed on insulation layer 740.

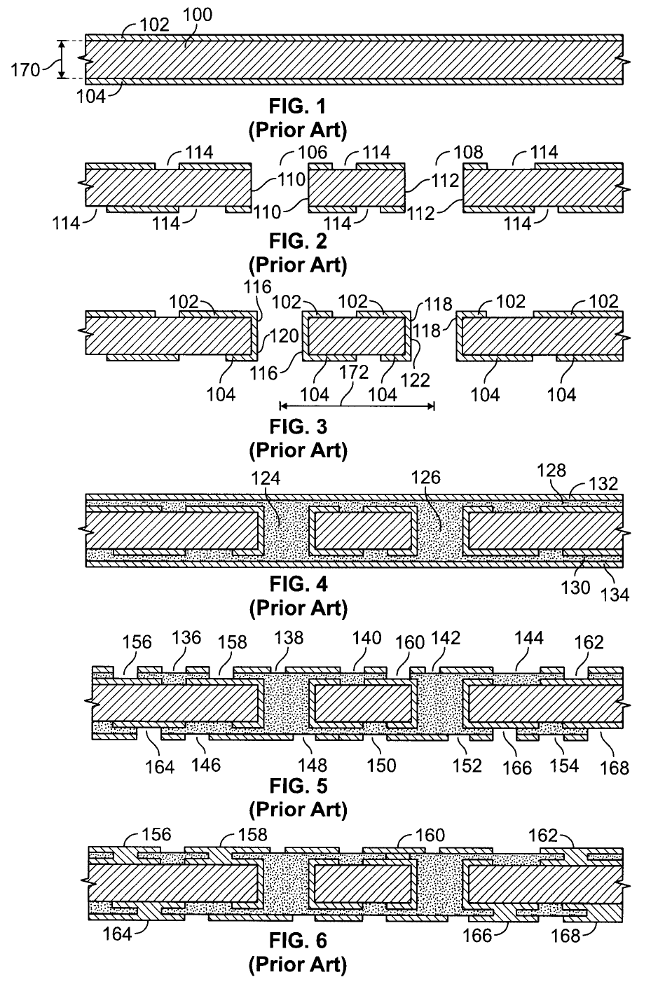

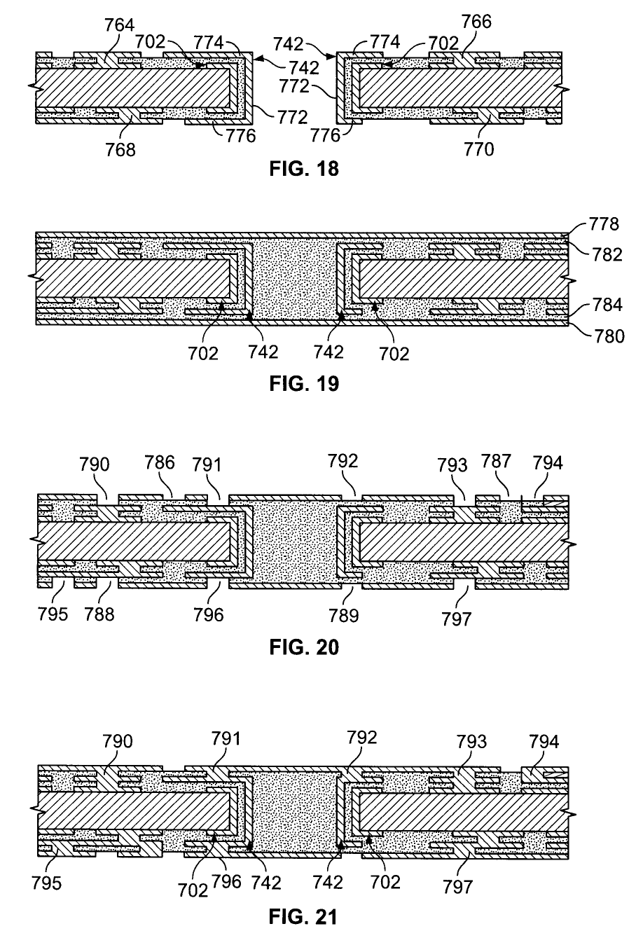

The method, as shown in block 618, also includes forming an inner through hole structure 748 within the outer plated through hole 710. As described above, any suitable method, such as drilling or using a laser, may be used to form the inner through hole structure 748. The method may also include etching portions of the third and fourth metal layer portions 744, 746. Examples of such etched regions are shown in FIG. 17 and designated 750, 752, 754, 756, 758, 760, and 762. Furthermore, electrically conductive portions, e.g., micro vias, may be formed, such as micro vias 764, 766, 768, and 770. Electrically conductive portions, as known in the art and as discussed in relation to FIGS. 1 through 6, may connect different layers of a circuit substrate. As shown in FIG. 18, for example, micro via 764 and 766 connect the first metal layer portion 704 with the third metal layer portion 744. Similarly, micro vias 768 and 770 connect second metal layer portion 706 with fourth metal layer portion 746.

As shown in block 620, before ending in block 622, the method also includes plating the inner through hole structure 748 with a second conductive material 772 to form an inner plated through hole structure 742. As one skilled in the art will appreciate, second conductive material 772 may be the same material as conductive material 730, which may even be the same type of material as any of the metal layers. The inner plated through hole structure 742 includes second conductive material 772 and portions of the third and fourth metal layer portions, generally designated 774, 776.

As one skilled in the art will appreciate, the steps may be performed in any suitable order, may include additional steps, different steps or may repeat some of the steps. For example, FIGS. 19, 20, and 21 illustrate repeating some of the steps to add additional layers to the circuit substrate. FIG. 19 further includes a fifth and sixth metal layer portions 778, 780 added onto additional insulation layers 782 and 784. FIG. 20 shows additional etched regions 786, 787, 788, and 789. FIG. 20 also shows additional electrically conductive portions, e.g., micro vias, 790, 791, 792, 793, 794, 795, 796, and 797. As shown in FIG. 21, plating fills in the newly formed micro vias.

As another example, the method may further include concentrically locating the inner plated through hole structure 742 within the outer plated through hole structure 702.

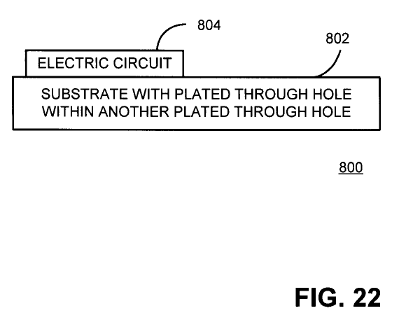

As one skilled in the art will readily recognize and as shown in FIG. 22, a circuit assembly 800 may include a substrate with a plated through hole structure within another plated through hole structure 802 operatively coupled to at least one electronic circuit 804. As discussed above, an electronic circuit such as electronic circuit 804 may include an integrated circuit, a resistor, a memory, or any other suitable electronic/optical circuit or component or other components (connectors, etc.) as desired.

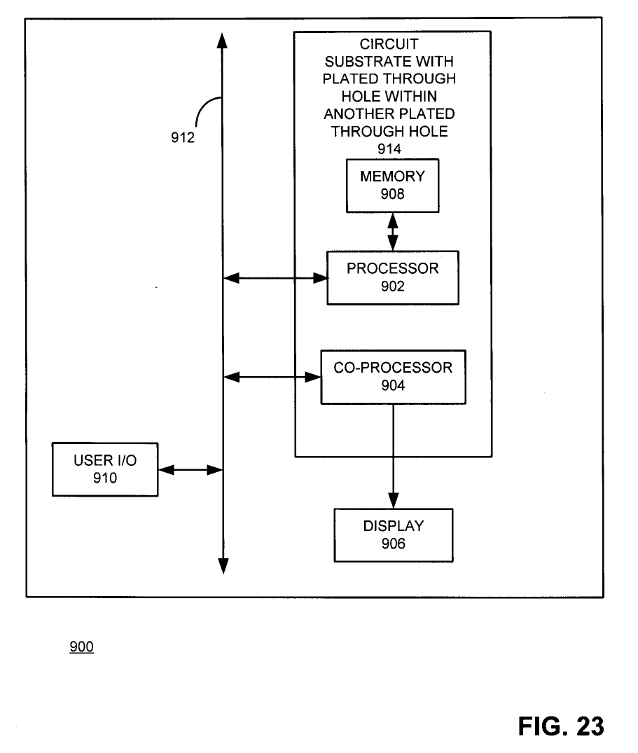

Referring now to FIG. 23, a substrate with a plated through hole within another plated through hole may be implemented in a device 900, such as a wireless phone, a mobile and/or stationary computer, a printer, a LAN interface (wireless and/or wired), a media player, a video encoder and/or decoder, and/or any other suitable device. The device 900 may include, among other things, a processor 902, such as one or more central processing units (or cores) or any suitable circuitry. The device 900 may also include a co-processor 904, such as a graphics processor (core). Co-processor 904 may be connected to a display 906, which may be a part of the device itself, i.e., it is embedded in the device, or it may be permanently or removably attached by a cable or any suitable means.

The device 900 may also include memory 908, such as RAM, ROM, discrete logic, dynamic, low latency nonvolatile memory, flash, and/or any suitable optical magnetic or electronic data storage that stores executable instructions that may be executed by one or more processors 902 or that stores data of any desired type. The memory 908 may also include non-local memory such as networked memory available via an intranet server, Internet server, or any suitable non-local memory.

The device may also include a user I/O 910 or any other suitable circuits, interfaces, structures, or functional operations. The user I/O 910 may include, for example, a keyboard, a touch screen, a mouse, and/or any other suitable device. The processor 902, co-processor 904, memory 908, user I/O 910, and/or any other suitable device may communicate via a bus 912 and/or any other suitable mechanism, whether the bus is local, wireless, a network connection, or any suitable link.

Furthermore, device 900 may include a circuit substrate 914 with a plated through hole within another plated through hole as described above. Circuit substrate 914 may be operatively coupled to one or more electronic components, such as a processor 902, co-processor 904, memory 908, and/or any other suitable electronic component.

As noted above, a circuit substrate, such as circuit substrate 200 (having a plated through hole structure within another plated through hole structure), among other advantages, may operate with improved performance, especially at higher frequencies, because the plated through hole structure 206 can reduce inductance. It is further recognized that using a plated through hole within another plated through hole may also increase the mechanical robustness of a circuit substrate by requiring fewer plated through holes in a circuit substrate and by not requiring the reduction of the thickness of an insulation core in a circuit substrate.

The above detailed description and the examples described herein have been presented for the purposes of illustration and description only and not by limitation. It is further contemplated that the present disclosure, as understood by those skilled in the art, cover any and all modifications, variations, or equivalents that fall within the spirit and scope of the basic underlying principles disclosed above and claimed herein.

What is claimed is:

1. A circuit substrate comprising:
at least an outer plated through hole structure; and
at least an inner plated through hole structure located within the outer plated through hole structure.

2. The circuit substrate of claim 1 comprising an insulation material interposed between the outer plated through hole structure and the inner plated through hole structure and wherein the inner plated through hole structure is concentrically located within the outer plated through hole structure.

3. The circuit substrate of claim 1 wherein the outer plated through hole structure comprises a portion configured in a cylindrical shape and wherein the inner plated through hole structure comprises a portion configured in a cylindrical shape.

4. The circuit substrate of claim 1 comprising a core and wherein the outer plated through hole structure comprises a first metal layer configured over the core defining an outer plated through hole and wherein the inner plated through hole structure located within the outer plated through hole structure comprises a second metal layer positioned inside of the outer plated through hole and an insulation material interposed between the first metal layer of the outer plated through hole structure and the second metal layer of the inner plated through hole structure.

5. The circuit substrate of claim 1 wherein the inner plated through hole structure comprises electrically conductive portions that electrically couple metal of the inner plated though hole structure to other layers of the substrate.

6. A circuit assembly comprising:
a circuit substrate comprising:
at least an outer plated through hole structure; and
at least an inner plated through hole structure located within the outer plated through hole structure; and
at least one electronic circuit operatively coupled to the circuit substrate.

7. The circuit assembly of claim 6 wherein the circuit substrate comprises an insulation material interposed between the outer plated through hole structure and the inner plated through hole structure and wherein the inner plated through hole structure is concentrically located within the outer plated through hole structure.

8. The circuit substrate of claim 6 wherein the outer plated through hole structure comprises a portion configured in a cylindrical shape and wherein the inner plated through hole structure comprises a portion configured in a cylindrical shape.

9. The circuit substrate of claim 6 comprising a core and wherein the outer plated through hole structure comprises a first metal layer configured over the core defining an outer plated through hole and wherein the inner plated through hole structure located within the outer plated through hole structure comprises a second metal layer positioned inside of the outer plated through hole and an insulation material interposed between the first metal layer of the outer plated through hole structure and the second metal layer of the inner plated through hole structure.

10. The circuit substrate of claim 6 wherein the inner plated through hole structure comprises electrically conductive portions that electrically couple metal of the inner plated though hole structure to other layers of the substrate.

11. A device comprising:
a circuit assembly comprising:
a circuit substrate comprising:
at least an outer plated through hole structure; and
at least an inner plated through hole structure located within the outer plated through hole structure; and
at least one electronic circuit operatively coupled to the circuit substrate.

12. The device of claim 11 wherein the circuit substrate comprises an insulation material interposed between the outer plated through hole structure and the inner plated through hole structure and wherein the inner plated through hole structure is concentrically located within the outer plated through hole structure.

13. The circuit substrate of claim 11 wherein the outer plated through hole structure comprises a portion configured in a cylindrical shape and wherein the inner plated through hole structure comprises a portion configured in a cylindrical shape.

14. The circuit substrate of claim 11 comprising a core and wherein the outer plated through hole structure comprises a first metal layer configured over the core defining an outer plated through hole and wherein the inner plated through hole structure located within the outer plated through hole structure comprises a second metal layer positioned inside of the outer plated through hole and an insulation material interposed between the first metal layer of the outer plated through hole structure and the second metal layer of the inner plated through hole structure.

15. The circuit substrate of claim 11 wherein the inner plated through hole structure comprises electrically conductive portions that electrically couple metal of the inner plated though hole structure to other layers of the substrate.

16. A method for making a circuit substrate comprising:
forming an inner plated through hole structure within an outer plated through hole structure in a circuit substrate.

17. The method of claim 16 wherein forming the inner plated through hole structure within the outer plated through hole structure comprises:
placing an insulation material over a plated through hole of the outer plated through hole structure; and
forming a metal plated through hole over the insulation material.

18. A method for making a circuit substrate comprising:
forming an outer plated through hole structure by:
applying a first metal layer portion and a second metal layer portion over an insulation core wherein the insulation core is interposed between the first and second metal layer portions;
forming an outer through hole structure defined at least in part by an inner surface of the core;
plating the outer through hole structure with a first conductive material to form an outer plated through hole structure that includes the first and second metal layer portions;
placing a second insulation material within the outer plated through hole structure;
forming an insulation layer on each of the first and second metal layer portions;
forming an inner plated through hole structure by:
placing a third metal layer portion and a fourth metal layer portion over each of the insulation layers;
forming an inner through hole structure within the outer plated through hole defined at least in part by an inner surface of the second insulation material; and
plating the inner through hole structure with a second conductive material to form an inner plated through hole structure that includes the third and fourth metal layer portions.

19. The method of claim 18 further comprising concentrically locating the inner plated through hole structure within the outer plated through hole structure.

20. The method of claim 18 further comprising forming electrically conductive portions that electrically couple metal of the inner plated through hole structure to other layers of the substrate.
